(19) United States
(12) Patent Application Publication
(10) Pub. No.: US 2024/0126306 A1
(43) Pub. Date: Apr. 18, 2024

(54) CENTER, MANAGEMENT METHOD, AND STORAGE MEDIUM

(71) Applicant: DENSO CORPORATION, Kariya-City (JP)

(72) Inventors: Masatoshi KOMIYAMA, Kariya-City (JP); Kensho TAKI, Kariya-City (JP); Lingfei XIE, Kariya-City (JP); Shigeru KAJIOKA, Kariya-City (JP); Makiko TAUCHI, Kariya-City (JP)

(21) Appl. No.: 18/398,348

(22) Filed: Dec. 28, 2023

Related U.S. Application Data
(63) Continuation of application No. PCT/JP22/25385, filed on Jun. 24, 2022.

(30) Foreign Application Priority Data
Jul. 2, 2021 (JP) 2021-110900

(51) Int. Cl. G05D 1/692; G05D 1/698; G05D 109/10; G06F 30/20; G07C 5/00; G08G 1/00; G08G 1/13

(52) U.S. Cl. CPC G05D 1/692; G05D 1/6987; G06F 30/20; G07C 5/008; G08G 1/13; G08G 1/20; G05D 2109/10

(57) ABSTRACT

A center includes a vehicle related device, which is communicably connected with multiple in-vehicle devices, and a service related device communicably connected with a service providing unit. The vehicle related device generates, for each vehicle, a shadow using multiple pieces of vehicle data repeatedly acquired from the in-vehicle device of corresponding vehicle, and stores the generated shadow in a shadow storage unit. The service related device generates indices corresponding to respective shadows, each of which is assigned with the timing identification information, and stores the generated indices in an index storage unit provided in the service related device. The service related device acquires, from the index storage unit, one of the indices corresponding to a designated parameter, and the vehicle related device acquires one of the multiple pieces of vehicle data from the shadow storage unit using the one of the indices, which is acquired corresponding to the designated parameter.

### CROSS REFERENCE TO RELATED APPLICATIONS

The present application is a continuation application of International Patent Application No. PCT/JP2022/025385 filed on Jun. 24, 2022, which designated the U.S. and claims the benefit of priority from Japanese Patent Application No. 2021-110900 filed on Jul. 2, 2021. The entire disclosures of all of the above applications are incorporated herein by reference.

### TECHNICAL FIELD

The present disclosure relates to a center, a management method, and a management program that manage vehicle data.

### BACKGROUND

There has been known a digital twin simulation that reproduces, in a virtual space, a state of a real-world vehicle by collecting data from the vehicle.

### SUMMARY

A center includes a vehicle related device, which is communicably connected with multiple in-vehicle devices mounted on respective vehicles, and a service related device communicably connected with a service providing unit. The vehicle related device generates, for each of the multiple vehicles, a shadow using multiple pieces of vehicle data repeatedly acquired from the in-vehicle device of corresponding vehicle, and stores the generated shadow in a shadow storage unit. The service related device generates indices corresponding to respective shadows, each of which is assigned with the timing identification information, and stores the generated indices in an index storage unit provided in the service related device. The service related device acquires, from the index storage unit, one of the indices corresponding to a designated parameter, and the vehicle related device acquires one of the multiple pieces of vehicle data from the shadow storage unit using the one of the indices, which is acquired corresponding to the designated parameter.

### BRIEF DESCRIPTION OF DRAWINGS

Objects, features and advantages of the present disclosure will become apparent from the following detailed description made with reference to the accompanying drawings.

FIG. 1 is a block diagram illustrating a configuration of a mobility IoT system.

FIG. 2 is a block diagram illustrating a configuration of a data collection device.

FIG. 3 is a block diagram illustrating a configuration of a management center.

FIG. 4 is a functional block diagram illustrating a functional configuration of the data collection device.

FIG. 5 is a functional block diagram illustrating a functional configuration of the management center.

FIG. 6 is a diagram illustrating a configuration of a CAN frame.

FIG. 7 is a flowchart illustrating data standardization processing.

FIG. 8 is a diagram illustrating a configuration of a vehicle data conversion table.

FIG. 9 is a diagram illustrating a first layer of standardized vehicle data and a data format thereof.

FIG. 10 is a diagram illustrating a configuration of the standardized vehicle data.

FIG. 11 is a sequence diagram illustrating a procedure of generating the standardized vehicle data.

FIG. 12 is a flowchart illustrating a first half of data transmission processing.

FIG. 13 is a flowchart illustrating a second half of the data transmission processing.

FIG. 14 is a timing chart illustrating a data transmission timing.

FIG. 15 is a functional block diagram illustrating functional configurations of a mobility GW and a data management unit.

FIG. 16 is a diagram illustrating a configuration of a shadow.

FIG. 17 is a diagram illustrating a configuration of a latest index.

FIG. 18 is a diagram illustrating a configuration of an index.

FIG. 19 is a diagram illustrating a specific example of a request.

FIG. 20 is a block diagram illustrating a connection state of an ECU mounted on a vehicle.

### DETAILED DESCRIPTION

In response to the spread of mobility services, for example, there is provided a fleet service in which a service manager centrally manages vehicles by periodically collecting vehicle data such as GPS information from the vehicles and displaying the positions of the vehicles on a map display of a browser.

The format of the vehicle data varies for each vehicle manufacturer, for each vehicle, and for each shipping time. For this reason, the service installed in the vehicle needs to be developed in consideration of the difference in the format of the vehicle data. However, the cloud service is required to have a sense of speed in which the cloud service is quickly put on the market and improved while listening to the voice of users.

As a result of detailed studies by the inventors, it has been found that, in order to provide mobility services involving both an IT service provider and a vehicle manufacturer, it is necessary to satisfy both requirements on the service provider side and requirements on the vehicle manufacturer side.

According to an aspect of the present disclosure, a center includes a vehicle related device and a service related device.

The vehicle related device is communicably connected with multiple in-vehicle devices individually mounted on multiple vehicles, and performs data communication with the multiple in-vehicle devices. The service related device is communicably connected with a service providing unit, and performs data communication with the service providing unit.

The vehicle related device includes a shadow generation unit generating, for each of the multiple vehicles, a shadow using multiple pieces of vehicle data repeatedly acquired from the in-vehicle device of corresponding vehicle. Each of the multiple pieces of vehicle data generated as the shadow is assigned with vehicle identification information for identifying the corresponding vehicle and timing identification information for identifying a timing at which each of the multiple pieces of vehicle data is acquired. The shadow generation unit stores the shadow that includes the multiple pieces of vehicle data in a shadow storage unit provided in the vehicle related device.

The service related device includes an index generation unit and an index acquisition unit. The index generation unit generates indices corresponding to respective shadows, each of which is assigned with the timing identification information, and stores the generated indices in an index storage unit provided in the service related device. The index acquisition unit acquires, from the index storage unit, one of the indices corresponding to a designated parameter.

The vehicle related device further includes a data acquisition unit acquiring one of the multiple pieces of vehicle data from the shadow storage unit using the one of the indices, which is acquired corresponding to the designated parameter.

In the center having the above-described configuration, the vehicle related device includes shadow storage unit that stores shadows each of which is configured by multiple pieces of vehicle data, and the service related device includes the index storage unit that stores indices corresponding to respective shadows each of which is assigned with the timing identification information.

The service related device specifies the shadow by referring to the index (that is, without directly referring to the shadow). The index is associated with each shadow to which the timing identification information is assigned. Thus, the index does not depend on the vehicle manufacturer, the vehicle itself, and the shipping time of vehicle.

As a result, the center according to the present disclosure can cause the service developer to develop the service without considering the difference in the format of the vehicle data. Thus, the present disclosure can achieve both the requirement on the service provider side and the requirement on the vehicle manufacturer side.

According to another aspect of the present disclosure, a management method performed by a center is provided. The center includes a vehicle related device communicably connected with multiple in-vehicle devices, which are individually mounted on multiple vehicles, for performing data communication and a service related device communicably connected with a service providing unit for performing data communication.

The management method includes: causing the vehicle related device to repeatedly acquire multiple pieces of vehicle data from each of the multiple in-vehicle devices and generate, for each of the multiple vehicles, a shadow using the acquired multiple pieces of vehicle data, wherein each of the multiple pieces of vehicle data generated as the shadow is assigned with vehicle identification information for identifying the corresponding vehicle and timing identification information for identifying a timing at which each of the multiple pieces of vehicle data is acquired; causing the vehicle related device to store the multiple pieces of vehicle data in a shadow storage unit provided in the vehicle related device; causing the service related device to generate indices corresponding to respective shadows, each of which is assigned with the timing identification information, and store the generated indices in an index storage unit provided in the service related device; causing the service related device to acquire, from the index storage unit, one of the indices corresponding to a designated parameter; and causing the vehicle related device to acquire one of the multiple pieces of vehicle data from the shadow storage unit using the one of the indices, which is acquired corresponding to the designated parameter.

The management method of the present disclosure is a method performed by the center of the present disclosure. By performing the method, an effect similar to that of the center of the present disclosure can be obtained.

According to another aspect of the present disclosure, a computer-readable non-transitory storage medium stores a management program for causing a computer in a center, which includes the vehicle related device and the service related device, to function as the shadow generation unit, the index generation unit, the index acquisition unit, and the data acquisition unit.

A computer controlled by the management program of the present disclosure can constitute a part of the center. Thus, the management program can provide an effect similar to that provided by the center of the present disclosure.

According to another aspect of the present disclosure, a center includes a vehicle related device and a service related device. The vehicle related device includes a shadow generation unit, a first acquisition unit, and a vehicle control unit. The service related device includes an access application programming interface and a second acquisition unit.

The shadow generation unit generates, for each of the multiple vehicles, a shadow using multiple pieces of vehicle data repeatedly acquired from the in-vehicle device of corresponding vehicle. Each of the multiple pieces of vehicle data generated as the shadow being assigned with vehicle identification information for identifying the corresponding vehicle and timing identification information for identifying a timing at which each of the multiple pieces of vehicle data is acquired, and the shadow generation unit stores the shadow that includes the multiple pieces of vehicle data in a shadow storage unit provided in the vehicle related device. The first acquisition unit acquires one of the multiple pieces of vehicle data from the shadow storage unit, and the vehicle control unit relays, to one of the multiple vehicles, a request to access the corresponding vehicle.

The access application programming interface receives a request from the service providing unit, and the second acquisition unit requests the vehicle related device to acquire one of the multiple pieces of vehicle data in response to the request received by the access application programming interface.

In the center of the present disclosure with the above configuration, since the vehicle data can be acquired from the shadow in response to the request from the service providing unit, it is possible to cause the service developer to develop the service without considering the difference in the format of the vehicle data, and it is possible to achieve both the requirement on the service provider side and the requirement on the vehicle manufacturer side.

According to another aspect of the present disclosure, a management method performed by a center is provided. The center includes a vehicle related device and a service related device.

The management method includes: causing the vehicle related device to repeatedly acquire multiple pieces of vehicle data from each of the multiple in-vehicle devices and generate, for each of the multiple vehicles, a shadow using the acquired multiple pieces of vehicle data, wherein each of the multiple pieces of vehicle data generated as the shadow is assigned with vehicle identification information for identifying the corresponding vehicle and timing identification information for identifying a timing at which each of the multiple pieces of vehicle data is acquired; causing the vehicle related device to store the multiple pieces of vehicle data in a shadow storage unit provided in the vehicle related device; causing the vehicle related device to acquire one of the multiple pieces of vehicle data from the shadow storage unit; causing the vehicle related device to relay, to one of the multiple vehicles, a request to access the corresponding vehicle; causing the service related device to receive a request from the service providing unit; and causing the service related device to request the vehicle related device to acquire one of the multiple pieces of vehicle data in response to the request received from the service providing unit.

The above management method of the present disclosure is a method performed by the center of the present disclosure. By performing the management method, an effect similar to that of the center of the present disclosure can be obtained.

According to another aspect of the present disclosure, a computer-readable non-transitory storage medium stores a management program for causing a computer in a center, which includes a vehicle related device and a service related device, to function as a shadow generation unit, a first acquisition unit, a vehicle control unit, an access API, and a second acquisition unit.

A computer controlled by the management program of the present disclosure can constitute a part of the center of the present disclosure, and can obtain an effect similar to that of the center of the present disclosure.

Hereinafter, embodiments of the present disclosure will be described with reference to the drawings.

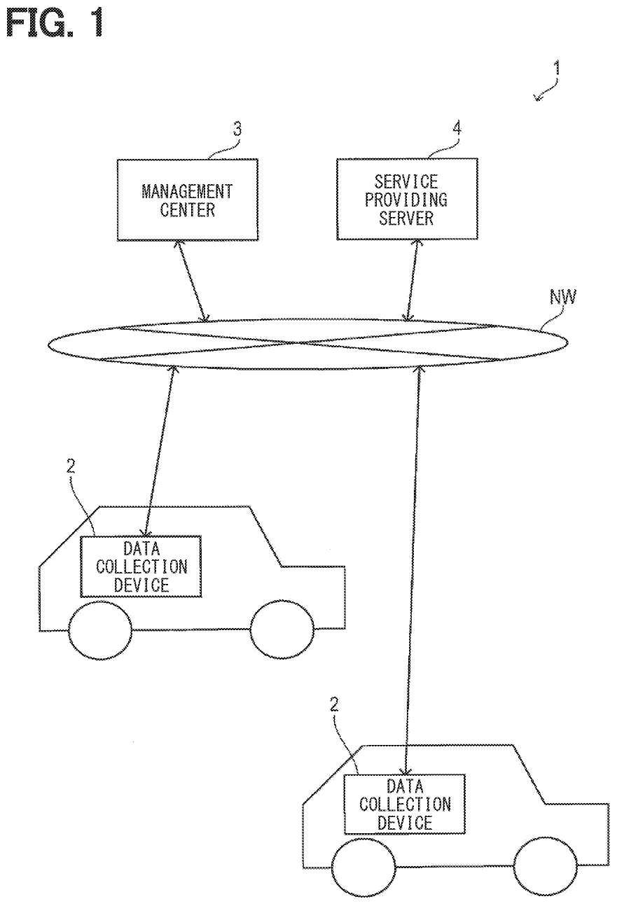

As illustrated in FIG. 1, a mobility IoT system 1 of the present embodiment includes multiple data collection devices 2, a management center 3, and a service providing server 4. IoT stands for Internet of Things.

The data collection device 2 is mounted on a vehicle and has a function of performing data communication with the management center 3 via a wide area wireless communication network NW.

The management center 3 is a device that manages the mobility IoT system 1. The management center 3 has a function of performing data communication with multiple data collection devices 2 and the service providing server 4 via the wide area wireless communication network NW.

The service providing server 4 is, for example, a server installed to provide a service for managing the operation of the vehicle. Note that the mobility IoT system 1 may include multiple service providing servers with different service contents. The service providing server 4 may be configured as an on-premises server, may be configured as a cloud server, or may be configured as a server physically the same as the management center 3.

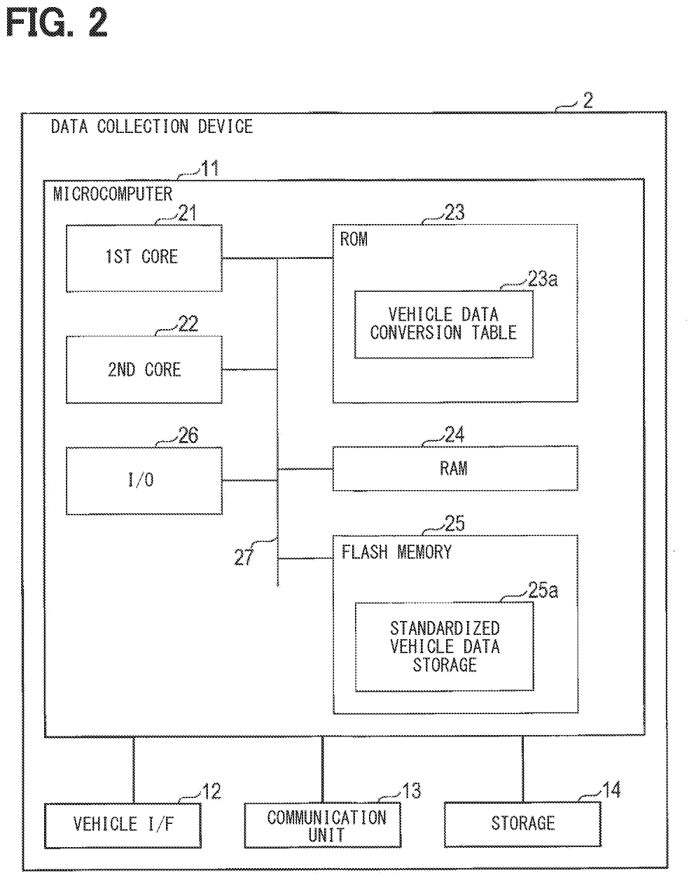

As illustrated in FIG. 2, the data collection device 2 includes a microcomputer 11, a vehicle interface (hereinafter, “vehicle I/F”) 12, a communication unit 13, and a storage unit 14.

The microcomputer 11 includes a first core 21, a second core 22, a ROM 23, a RAM 24, a flash memory 25, an input and output unit 26, and a bus 27.

Various functions of the microcomputer 11 are implemented by the first core 21 and the second core 22 executing programs stored in a non-transitory tangible storage medium. In this example, the ROM 23 corresponds to a non-transitory tangible storage medium storing a program. By executing the program, the method corresponding to the program is performed.

Note that part or all of the functions performed by the first core 21 and the second core 22 may be configured as hardware by one or multiple ICs or the like.

The flash memory 25 is a data-rewritable nonvolatile memory. The flash memory 25 includes a standardized vehicle data storage unit 25a that stores standardized vehicle data to be described later.

The input and output unit 26 is a circuit for inputting and outputting data between the outside of the microcomputer 11 and the first core 21 and the second core 22.

The bus 27 connects the first core 21, the second core 22, the ROM 23, the RAM 24, the flash memory 25, and the input and output unit 26 in such a manner that data can be input and output to and from each other.

The vehicle I/F 12 is an input and output circuit for inputting and outputting signals to and from an electronic control device, a sensor, and the like mounted on the vehicle.

The vehicle I/F 12 includes a power supply voltage input port, a general-purpose input and output port, a CAN communication port, an Ethernet communication port, and the like.

The power supply voltage input port includes a +B voltage port to which a +B voltage is input and an IG voltage port to which an IG voltage is input. Note that the vehicle I/F 12 includes a protection circuit including a DC-DC converter and a Zener diode. As a result, the power supply voltage input port is configured to be compatible with both an input of a vehicle voltage of 12 V and an input of a vehicle voltage of 48 V.

The CAN communication port is a port for transmitting and receiving data in accordance with the CAN communication protocol. The Ethernet communication port is a port for transmitting and receiving data on the basis of the Ethernet communication protocol. CAN stands for Controller Area Network. CAN is a registered trademark. Ethernet is a registered trademark.

Another electronic control device mounted on the vehicle is connected to the CAN communication port and the Ethernet communication port. As a result, the data collection device 2 can transmit and receive a communication frame to and from another electronic control device.

The communication unit 13 performs data communication with the management center 3 via the wide area wireless communication network NW.

The storage unit 14 is a storage device for storing various data.

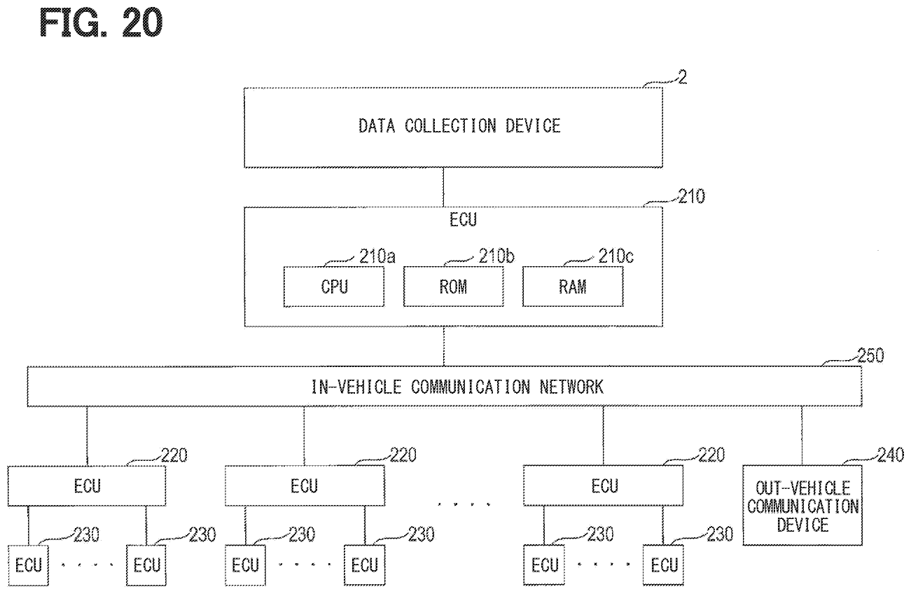

As illustrated in FIG. 20, one ECU 210, multiple ECUs 220, multiple ECUs 230, an out-vehicle communication device 240, and an in-vehicle communication network 250 are mounted on the vehicle. ECU stands for Electronic Control Unit.

The ECU 210 overall controls multiple ECUs 220 to implement cooperative control of the entire vehicle.

The ECU 220 is provided for each domain divided based on the functions in the vehicle, and mainly executes the control of multiple ECUs 230 present in the domain. Each ECU 220 is connected to a subordinate ECU 230 via a lower layer network (for example, CAN) individually provided. The ECU 220 has a function of centrally managing access authority and the like to the subordinate ECUs 230 and performing authentication and the like of a user. The domain includes, for example, a powertrain, a body, a chassis, a cockpit, and the like.

The ECU 230 connected to the ECU 220 belonging to the powertrain domain includes, for example, an ECU 230 that controls an engine, an ECU 230 that controls a motor, an ECU 230 that controls a battery, and the like.

The ECU 230 connected to the ECU 220 belonging to the body domain includes, for example, an ECU 230 that controls an air conditioner, an ECU 230 that controls a door, and the like.

The ECU 230 connected to the ECU 220 belonging to the chassis domain includes, for example, an ECU 230 that controls a brake, an ECU 230 that controls a steering, and the like.

The ECU 230 connected to the ECU 220 belonging to the cockpit domain includes, for example, an ECU 230 that controls meter and navigation display, an ECU 230 that controls an input device operated by an occupant of the vehicle, and the like.

The out-vehicle communication device 240 performs data communication with a communication device outside the vehicle (for example, a cloud server) via the wide area wireless communication network NW.

The in-vehicle communication network 250 includes CAN FD and Ethernet. CAN FD stands for CAN with Flexible Data Rate. The CAN FD connects the ECU 210, each ECU 220, and the out-vehicle communication device 240 via a bus. The Ethernet individually connects the ECU 210, each ECU 220, and the out-vehicle communication device 240.

The ECU 210 is an electronic control device mainly composed of a microcomputer including a CPU 210a, a ROM 210b, a RAM 210c, and the like. Various functions of the microcomputer are implemented by the CPU 210a executing programs stored in a non-transitory tangible storage medium. In this example, the ROM 210b corresponds to a non-transitory tangible storage medium storing a program. By executing the program, the method corresponding to the program is performed. Note that part or all of the functions performed by the CPU 210a may be configured as hardware by one or multiple ICs or the like. In addition, one microcomputer may constitute the ECU 210, or multiple microcomputers may constitute the ECU 210.

Each of the ECU 220, the ECU 230, and the out-vehicle communication device 240 is an electronic control device mainly composed of a microcomputer including a CPU, a ROM, a RAM, and the like, similarly to the ECU 210. In addition, one microcomputer may constitute each of the ECU 220, the ECU 230, and the out-vehicle communication device 240, or multiple microcomputers may constitute each of the ECU 220, the ECU 230, and the out-vehicle communication device 240. The ECU 220 is an ECU that overall controls one or more ECUs 230, and the ECU 210 is an ECU that overall controls one or more ECUs 220 or overall controls the ECUs 220 and 230 of the entire vehicle including the out-vehicle communication device 240.

The data collection device 2 is connected to the ECU 210 so as to enable data communication with the ECU 210. That is, the data collection device 2 receives information of the ECUs 210, 220, and 230 via the ECU 210. In addition, the data collection device 2 transmits a request related to vehicle control to the ECU 210 or to the ECUs 220 and 230 via the ECU 210.

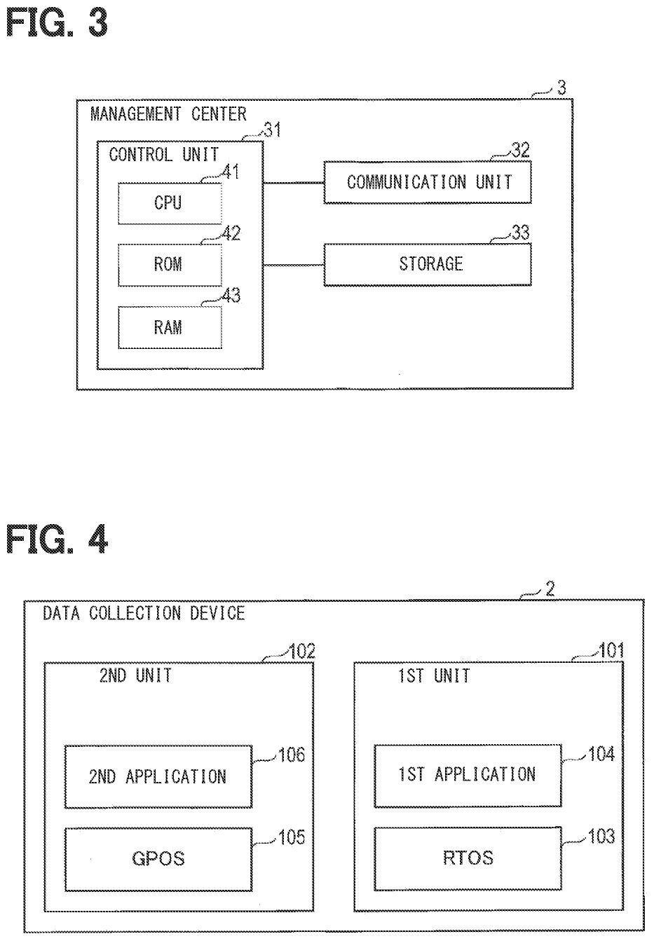

As illustrated in FIG. 3, the management center 3 includes a control unit 31, a communication unit 32, and a storage unit 33.

The control unit 31 is an electronic control device mainly composed of a microcomputer including a CPU 41, a ROM 42, a RAM 43, and the like. Various functions of the microcomputer are implemented by the CPU 41 executing programs stored in a non-transitory tangible storage medium. In this example, the ROM 42 corresponds to a non-transitory tangible storage medium storing a program. By executing the program, the method corresponding to the program is performed. Note that part or all of the functions performed by the CPU 41 may be configured as hardware by one or multiple ICs or the like. In addition, one microcomputer may constitute the control unit 31, or multiple microcomputers may constitute the control unit 31.

The communication unit 32 performs data communication with multiple data collection devices 2 and the service providing server 4 via the wide area wireless communication network NW.

The storage unit 33 is a storage device for storing various data.

As illustrated in FIG. 4, the data collection device 2 includes a first unit 101 as a functional block implemented by the first core 21 executing a program stored in the ROM 23. The data collection device 2 includes a second unit 102 as a functional block implemented by the second core 22 executing the program stored in the ROM 23.

The first unit 101 includes a real-time operating system (hereinafter, “RTOS”) 103 and a first application 104.

The first application 104 performs various processing for controlling the vehicle. The first application 104 is configured to be able to access the standardized vehicle data storage unit 25a of the flash memory 25 and refer to standardized vehicle data in order to perform various processing for controlling the vehicle.

The RTOS 103 manages the first application 104 in such a manner that the real time property of the processing performed by the first application 104 can be ensured.

The second unit 102 includes a general-purpose operating system (hereinafter, “GPOS”) 105 and a second application 106.

The second application 106 performs processing related to a service provided by the service providing server 4. The second application 106 is configured to be able to access the standardized vehicle data storage unit 25a of the flash memory 25 and refer to standardized vehicle data in order to perform the processing related to the service.

The GPOS 105 is basic software installed in the data collection device 2 in order to operate various applications, and manages the second application 106.

Note that the data collection device 2 may cause a single-core microcomputer to implement the operation in the RTOS 103 and the operation in the GPOS 105 by using a hypervisor.

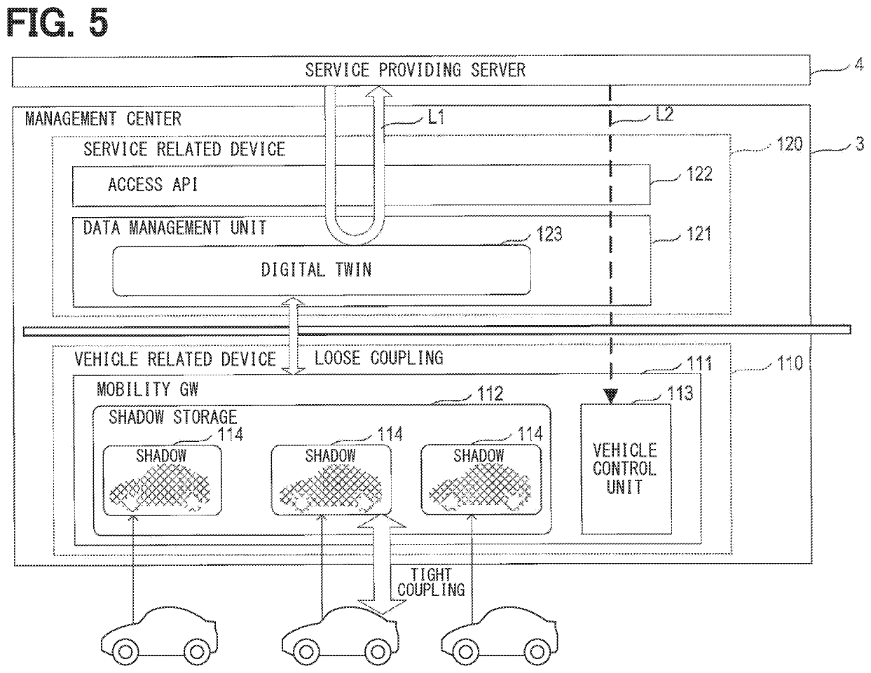

As illustrated in FIG. 5, the management center 3 includes a vehicle related device 110 and a service related device 120 as functional blocks implemented by the CPU 41 executing a program stored in the ROM 42. The side close to the access to the vehicle is referred to as the vehicle related device 110, the side close to the access from the service providing server 4 is referred to as the service related device 120, the functional block is divided into two, and these two functional blocks are loosely coupled.

The method of implementing these components constituting the management center 3 is not limited to software, and some or all of the components may be implemented by using one or multiple pieces of hardware. For example, in a case where the function is implemented by an electronic circuit which is hardware, the electronic circuit may be implemented by a digital circuit including a large number of logic circuits, an analog circuit, or a combination thereof.

The vehicle related device 110 manages access to the vehicle and data received from the vehicle. The vehicle related device 110 includes a mobility gateway (hereinafter, “mobility GW”) 111. The mobility GW 111 has a function of managing data received from the vehicle in addition to a function of relaying an access request to the vehicle to the vehicle.

The mobility GW 111 includes a shadow storage unit 112 and a vehicle control unit 113. The shadow storage unit 112 stores a shadow 114 that accommodates vehicle data for each vehicle on which the data collection device 2 is mounted. The shadow 114 indicates a vehicle data group of a certain vehicle. The vehicle control unit 113 has a function of controlling the vehicle on which the data collection device 2 is mounted on the basis of an instruction from the service providing server 4.

The service related device 120 receives a request from the service providing server 4 and provides vehicle data. The service related device 120 includes a data management unit 121 and an access API 122. API stands for Application Programming Interface.

The data management unit 121 has a function of managing a digital twin 123, which is a virtual space for providing vehicle access independent of a change in the connection state of the vehicle. The data management unit 121 manages data necessary for accessing vehicle data managed by the vehicle related device 110.

The access API 122 is a standard interface for the service providing server 4 to access the mobility GW 111 and the data management unit 121. The access API 122 provides the service providing server 4 with an API for accessing a vehicle and acquiring vehicle data.

Next, processing performed by the vehicle I/F 12 will be described.

When receiving a communication frame, the vehicle I/F 12 determines the communication protocol of the communication frame on the basis of the communication port that has received the communication frame. Specifically, for example, in a case where the communication frame is received at a CAN communication port, the vehicle I/F 12 determines that the communication protocol of the received communication frame is the CAN communication protocol. In addition, for example, in a case where the communication frame is received at an Ethernet communication port, the vehicle I/F 12 determines that the communication protocol of the received communication frame is the Ethernet communication protocol.

The vehicle I/F 12 then determines whether or not the communication frame is necessary on the basis of the identification information of the communication frame, and outputs the received communication frame to the first unit 101 when determining that the communication frame is necessary.

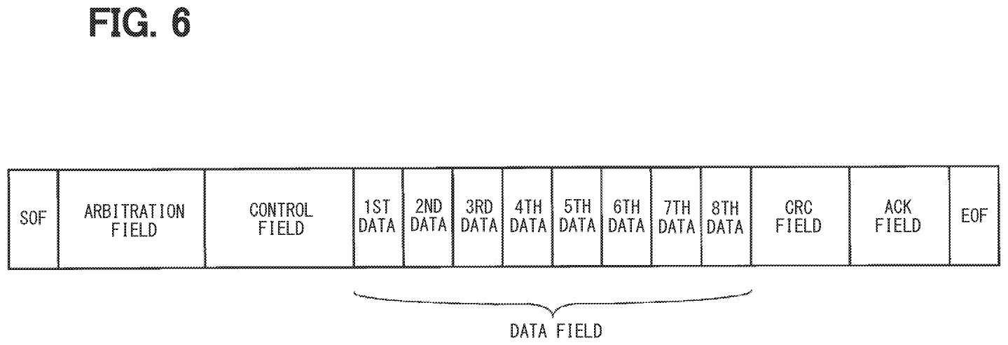

As illustrated in FIG. 6, the CAN frame includes a start of frame, an arbitration field, a control field, a data field, a CRC field, an ACK field, and an end of frame. Note that the arbitration field includes a 11 bit or 29 bit identifier (that is, ID) and 1 bit RTR bit.

In addition, the 11 bit identifier used in CAN communication is referred to as CANID. The CANID is preset on the basis of the content of data included in the CAN frame, the transmission source of the CAN frame, the transmission destination of the CAN frame, and the like.

The data field is a payload including first data, second data, third data, fourth data, fifth data, sixth data, seventh data, and eighth data each of which is 8 bits (that is, one byte). Hereinafter, each of the first to eighth data in the data field is also referred to as CAN data.

Therefore, when receiving the CAN frame, the vehicle I/F 12 determines whether or not the received CAN frame is necessary on the basis of the CANID.

Next, processing performed by the first unit 101 will be described.

When acquiring the communication frame output from the vehicle I/F 12, the first unit 101 extracts identification information and a payload from the communication frame, generates standard format data including the identification information and the payload, and stores the generated standard format data in the flash memory 25. For example, when acquiring a CAN frame, the first unit 101 generates standard format data including a CANID and first to eighth data. Here, the identification information (second identification information) included in the standard format data does not need to be the same as the identification information (first identification information) extracted from the communication frame. For example, unique second identification information may be generated using the first identification information, or the second identification information may be generated by conversion using the identification information of the communication protocol and the first identification information.

Note that, in a case where the standard format data including the same identification information as that in the generated standard format data has already been stored in the flash memory 25, the first unit 101 overwrites and stores the standard format data, thereby updating the standard format data. That is, the flash memory 25 stores the latest standard format data for the same identification information.

Next, the procedure of data standardization processing performed by the second unit 102 will be described. The data standardization processing is processing repeatedly performed during the operation of the microcomputer 11.

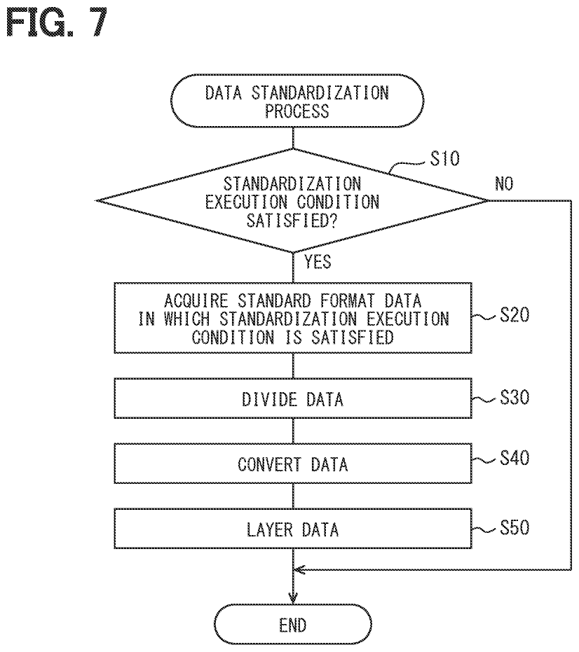

When the data standardization processing is performed, as illustrated in FIG. 7, the second core 22 first determines whether or not a preset standardization execution condition is satisfied in S10.

The standardization execution condition is that at least one of a first high-frequency standardization condition, a second high-frequency standardization condition, a third high-frequency standardization condition, a first low-frequency standardization condition, a second low-frequency standardization condition, an event standardization condition, or an invariant standardization condition to be described later is satisfied.

The first high-frequency standardization condition is that a preset first high-frequency standardization cycle (for example, 500 ms in the present embodiment) elapses.

The second high-frequency standardization condition is that a preset second high-frequency standardization cycle (for example, 2 s in the present embodiment) elapses.

The third high-frequency standardization condition is that a preset third high-frequency standardization cycle (for example, 4 s in the present embodiment) elapses.

The first low-frequency standardization condition is that a preset first low-frequency standardization cycle (for example, 30 s in the present embodiment) elapses.

The second low-frequency standardization condition is that a preset second low-frequency standardization cycle (for example, 300 s in the present embodiment) elapses.

The event standardization condition is that a preset event standardization cycle (for example, 12 hours in the present embodiment) elapses.

The invariant standardization condition is that the current processing in S10 is the first processing in S10 after the microcomputer 11 is activated.

Here, in a case where the standardization execution condition is not satisfied, the second core 22 ends the data standardization processing. On the other hand, in a case where the standardization execution condition is satisfied, in S20, the second core 22 acquires, from the flash memory 25, the standard format data corresponding to the satisfied standardization condition among the seven standardization conditions constituting the standardization execution condition. For example, in a case where the second high-frequency standardization condition is satisfied, the second core 22 acquires the standard format data corresponding to the second high-frequency standardization condition in S20.

In S30, the second core 22 then divides the data included in the standard format data. For example, since the standard format data generated from the CAN frame includes the CAN ID and the first to eighth data, the second core 22 divides the first to eighth data into one byte each and extracts eight pieces of CAN data.

In addition, in S40, the second core 22 refers to a vehicle data conversion table 23a stored in the ROM 23, and converts each piece of extracted data divided in S30 into a control label and vehicle data. The control label is identification information indicating the type of the vehicle data.

The vehicle data conversion table 23a includes normalization information and semanticization information.

The normalization information is information for normalizing the extracted data in such a manner that the same physical quantity has the same value regardless of the vehicle type and the vehicle manufacturer.

The semanticization information is information (for example, an arithmetic expression and a conversion table) for conversion into meaningful vehicle data using the normalized vehicle data into. The vehicle data before normalization may be used. Semanticization includes newly generating information that is not in the payload of the communication frame using an arithmetic expression or the like.

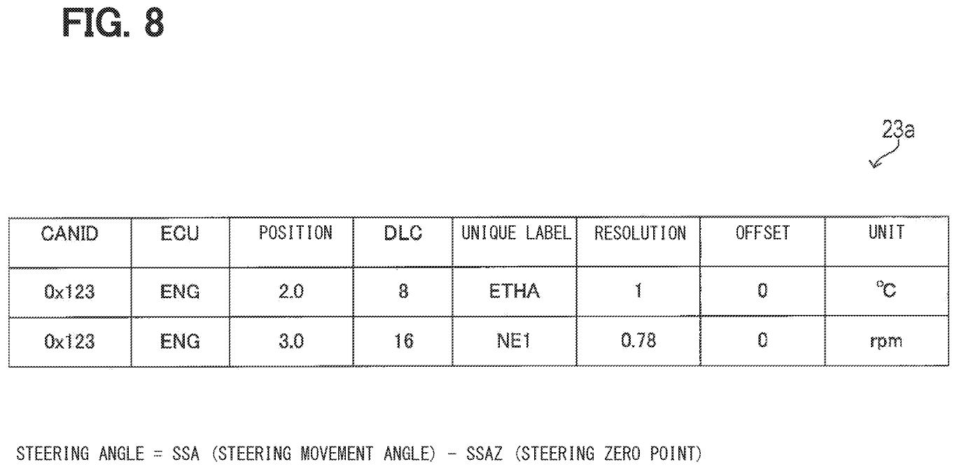

As illustrated in FIG. 8, the normalization information in the vehicle data conversion table 23a includes, for example, “CANID”, “ECU”, “position”, “DLC”, “unique label”, “resolution”, “offset”, and “unit” as setting items.

“ECU” is identification information indicating an ECU as the transmission source of the CAN frame. For example, “ENG” indicates an engine ECU.

“Position” is information indicating the position (for example, the bit position) of the CAN data in the data field. “DLC” is information indicating a data length. DLC stands for Data Length Code. That is, “DLC” bits of data are extracted from “position” in the data field.

“Unique label” is information indicating a control label. For example, “ETNA” indicates an intake air temperature, and “NE1” indicates an engine speed. “Resolution” is information indicating a numerical value per bit. “Offset” indicates the offset amount of a numerical value of the data. “Unit” indicates the unit of the data.

Therefore, data corresponding to “unique label” is extracted from the standard format data by “CANID”, “ECU”, “position”, “DLC”, and “unique label”. In addition, the extracted data is converted into vehicle data represented by “resolution”, “offset”, and “unit”.

For example, as illustrated in FIG. 8, the semanticization information in the vehicle data conversion table 23a is a conversion formula for performing conversion into “steering angle” by subtracting “steering zero point” with the control label “SSAZ” from “steering movement angle” with the control label “SSA”. As a result, the vehicle data representing “steering movement angle” and the vehicle data representing “steering zero point” are converted into the vehicle data representing “steering angle” with the meaning of “steering amount from the reference position”. “Unique label”, “unit”, and the like are assigned to vehicle data newly generated by semanticization.

The vehicle data conversion table 23a is also provided for data of “shift position” which is a predetermined control label. The data is converted into data indicating “P range”, “N range”, “D range”, and “R range” by the vehicle data conversion table 23a.

When the processing in S40 ends, the second core 22 layers the converted vehicle data in S50 and stores the layered data in the flash memory 25 as illustrated in FIG. 7. Specifically, the second core 22 stores the converted vehicle data in the corresponding area of the standardized vehicle data storage unit 25a provided in the flash memory 25.

The standardized vehicle data storage unit 25a stores standardized vehicle data configured by layering vehicle data.

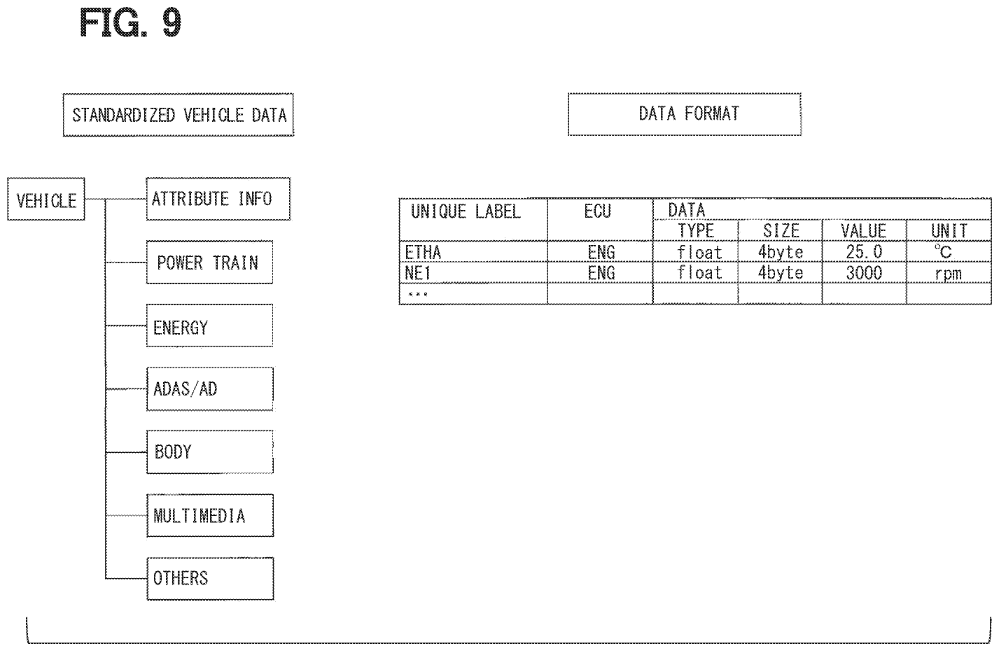

The standardized vehicle data is generated for each vehicle (that is, for each data collection device 2) and has a multi-layer structure. In the standardized vehicle data, one or multiple items are set in each of multiple layers. For example, as illustrated in FIG. 9, the standardized vehicle data includes “attribute information”, “powertrain”, “energy”, “ADAS/AD”, “body”, “multimedia”, and “others” as items set in a first layer, which is the highest level. ADAS stands for Advanced Driver Assistance System. AD stands for Autonomous Driving. These “attribute information”, “powertrain”, “energy”, and the like correspond to categories.

In addition, each vehicle data includes, as items, “unique label”, “ECU”, “data type”, “data size”, “data value”, and “data unit”. “Unique label” and “ECU” are as described above. “Data type”, “data size”, and “data unit” indicate a type, a size, and a unit related to a numerical value indicated by “data value”, respectively.

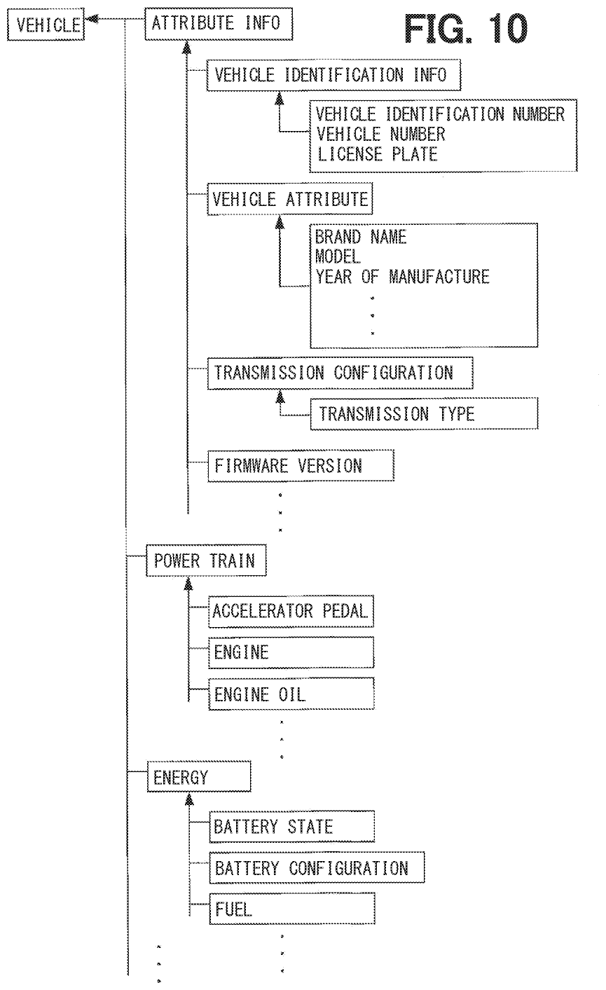

As illustrated in FIG. 10, the standardized vehicle data includes at least a second layer and a third layer in addition to the first layer. The second layer is a layer immediately below the first layer, and the third layer is a layer immediately below the second layer. The standardized vehicle data is an item set in the normalization and semanticization processing described above. The standardized vehicle data has a data structure, which is a layered structure.

For example, “attribute information”, which is an item in the first layer, includes “vehicle identification information”, “vehicle attribute”, “transmission configuration”, “firmware version”, and the like as items in the second layer. “Vehicle identification information” is a category name indicating information that can uniquely identify the vehicle. “Vehicle attribute” is a category name indicating the type of the vehicle. “Transmission information” is a category name indicating information related to a transmission. “Firmware version” is a category name indicating information related to the firmware of the vehicle.

In addition, “powertrain”, which is an item in the first layer, is a category name indicating powertrain information, and includes “accelerator pedal”, “engine”, “engine oil”, and the like as items in the second layer. “Accelerator pedal” includes one or more pieces of vehicle data such as the state and opening of an accelerator pedal. “Engine” includes one or more pieces of individual vehicle data such as an engine state and an engine speed. These second layers also correspond to categories. The same applies to other items in the first layer.

In addition, “energy”, which is an item in the first layer, is a category name indicating energy information, and includes “battery state”, “battery configuration”, “fuel”, and the like as items in the second layer.

“Vehicle identification information”, which is an item in the second layer, includes “vehicle identification number”, “vehicle number”, and “license plate” as items in the third layer. The items in the third layer include one or more pieces of individual vehicle data (also referred to as “items”).

“Vehicle attribute”, which is an item in the second layer, includes “brand name”, “model”, “year of manufacture”, and the like as items in the third layer.

“Transmission configuration”, which is an item in the second layer, includes “transmission type” as an item in the third layer. The items in the third layer are also referred to as items and are the minimum unit of the data structure.

For example, in a case where the control label of the converted vehicle data is “vehicle identification information”, the second core 22 stores the converted vehicle data in a storage area in which the first layer is “attribute information”, the second layer is “vehicle identification information”, and the third layer is “vehicle identification number” in the standardized vehicle data storage unit 25a.

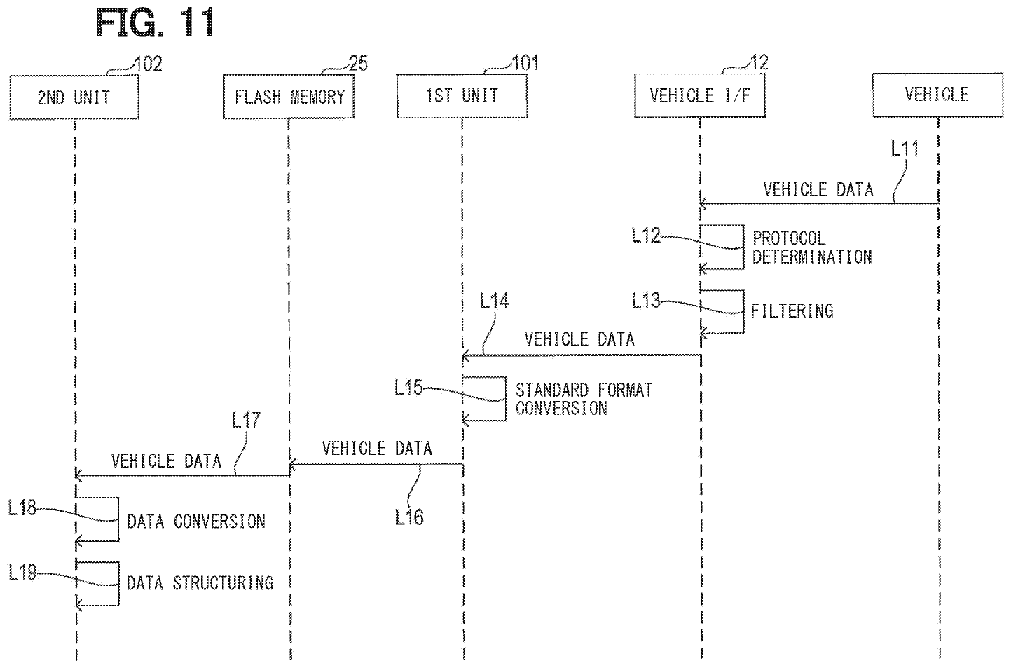

Next, the procedure in which the data collection device 2 generates the standardized vehicle data will be described using a sequence diagram illustrated in FIG. 11.

As indicated by an arrow L11, when the vehicle I/F 12 acquires vehicle data from the vehicle, the vehicle I/F 12 performs communication protocol determination as indicated by an arrow L12. In addition, the vehicle I/F 12 filters unnecessary vehicle data as indicated by an arrow L13, and outputs necessary vehicle data to the first unit 101 as indicated by an arrow L14.

When acquiring the vehicle data from the vehicle I/F 12, the first unit 101 converts the vehicle data into a standard format as indicated by an arrow L15, and stores the vehicle data converted into the standard format in the flash memory 25 as indicated by an arrow L16.

When acquiring the vehicle data converted into the standard format from the flash memory 25 as indicated by an arrow L17, the second unit 102 converts the acquired vehicle data as indicated by an arrow L18. In addition, as indicated by an arrow L19, the second unit 102 generates standardized vehicle data by structuring the converted data.

Next, the procedure of data transmission processing performed by the data collection device 2 will be described. The data transmission processing is processing repeatedly performed during the operation of the microcomputer 11.

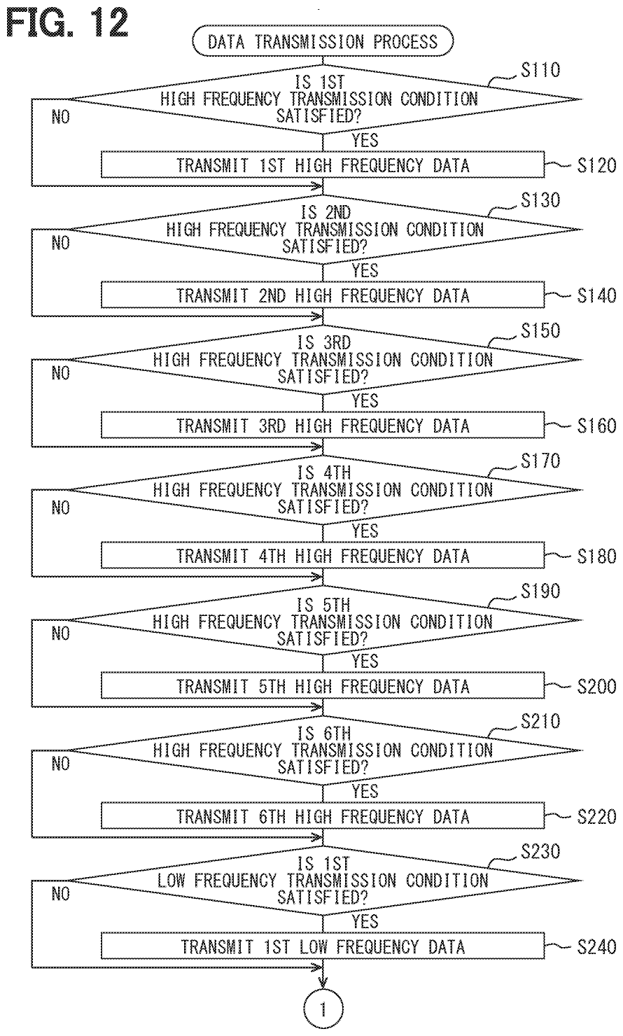

When the data transmission processing is performed, as illustrated in FIG. 12, the second core 22 first determines whether or not a preset first high-frequency transmission condition is satisfied in S110. The first high-frequency transmission condition is that mod {tx/(T×2)} is 0 where the current time is tx and the transmission interval set value (for example, 500 ms in the present embodiment) is T.

Here, in a case where the first high-frequency transmission condition is not satisfied, the second core 22 proceeds to S130. On the other hand, in a case where the first high-frequency transmission condition is satisfied, in S120, the second core 22 extracts the vehicle data set as the first high-frequency data in the vehicle data constituting the standardized vehicle data from the standardized vehicle data storage unit 25a, transmits the vehicle data to the management center 3, and proceeds to S130.

Note that the vehicle data constituting the standardized vehicle data is set to any one of second high-frequency data, third high-frequency data, fourth high-frequency data, fifth high-frequency data, sixth high-frequency data, first low-frequency data, second low-frequency data, third low-frequency data, fourth low-frequency data, event data, and invariant data, which will be described later, in addition to the first high-frequency data. A transmission frequency setting table that defines which of the first, second, third, fourth, fifth, and sixth high-frequency data, the first, second, third, and fourth low-frequency data, the event data, and the invariant data each vehicle data is set to is stored in advance in the flash memory 25.

When proceeding to S130, the second core 22 determines whether or not a preset second high-frequency transmission condition is satisfied. The second high-frequency transmission condition is that mod {(tx+T)/(T×2)} is 0.

Here, in a case where the second high-frequency transmission condition is not satisfied, the second core 22 proceeds to S150. On the other hand, in a case where the second high-frequency transmission condition is satisfied, in S140, the second core 22 extracts the vehicle data set as the second high-frequency data in the vehicle data constituting the standardized vehicle data from the standardized vehicle data storage unit 25a, transmits the vehicle data to the management center 3, and proceeds to S150.

When proceeding to S150, the second core 22 determines whether or not a preset third high-frequency transmission condition is satisfied. The third high-frequency transmission condition is that mod {tx/(T×8)} is 0.

Here, in a case where the third high-frequency transmission condition is not satisfied, the second core 22 proceeds to S170. On the other hand, in a case where the third high-frequency transmission condition is satisfied, in S160, the second core 22 extracts the vehicle data set as the third high-frequency data in the vehicle data constituting the standardized vehicle data from the standardized vehicle data storage unit 25a, transmits the vehicle data to the management center 3, and proceeds to S170.

When proceeding to S170, the second core 22 determines whether or not a preset fourth high-frequency transmission condition is satisfied. The fourth high-frequency transmission condition is that mod {(tx+T)/(T×8)} is 0.

Here, in a case where the fourth high-frequency transmission condition is not satisfied, the second core 22 proceeds to S190. On the other hand, in a case where the fourth high-frequency transmission condition is satisfied, in S180, the second core 22 extracts the vehicle data set as the fourth high-frequency data in the vehicle data constituting the standardized vehicle data from the standardized vehicle data storage unit 25a, transmits the vehicle data to the management center 3, and proceeds to S190.

When proceeding to S190, the second core 22 determines whether or not a preset fifth high-frequency transmission condition is satisfied. The fifth high-frequency transmission condition is that mod {tx/(T×16)} is 0.

Here, in a case where the fifth high-frequency transmission condition is not satisfied, the second core 22 proceeds to S210. On the other hand, in a case where the fifth high-frequency transmission condition is satisfied, in S200, the second core 22 extracts the vehicle data set as the fifth high-frequency data in the vehicle data constituting the standardized vehicle data from the standardized vehicle data storage unit 25a, transmits the vehicle data to the management center 3, and proceeds to S210.

When proceeding to S210, the second core 22 determines whether or not a preset sixth high-frequency transmission condition is satisfied. The sixth high-frequency transmission condition is that mod {(tx+T)/(T×16)} is 0.

Here, in a case where the sixth high-frequency transmission condition is not satisfied, the second core 22 proceeds to S230. On the other hand, in a case where the sixth high-frequency transmission condition is satisfied, in S220, the second core 22 extracts the vehicle data set as the sixth high-frequency data in the vehicle data constituting the standardized vehicle data from the standardized vehicle data storage unit 25a, transmits the vehicle data to the management center 3, and proceeds to S230.

When proceeding to S230, the second core 22 determines whether or not a preset first low-frequency transmission condition is satisfied. The first low-frequency transmission condition is that mod {tx/(T×120)} is 0.

Here, in a case where the first low-frequency transmission condition is not satisfied, the second core 22 proceeds to S250. On the other hand, in a case where the first low-frequency transmission condition is satisfied, in S240, the second core 22 extracts the vehicle data set as the first low-frequency data in the vehicle data constituting the standardized vehicle data from the standardized vehicle data storage unit 25a, transmits the vehicle data to the management center 3, and proceeds to S250.

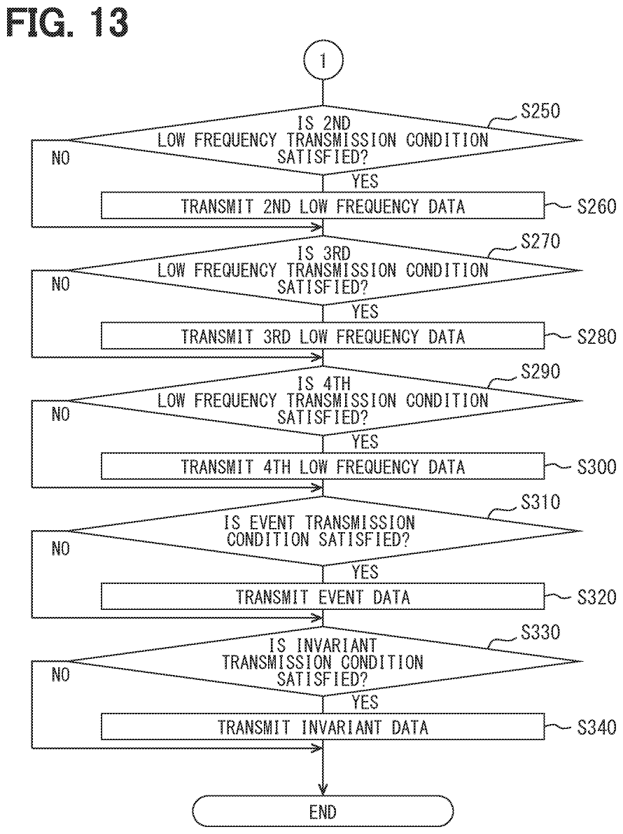

When proceeding to S250, the second core 22 determines whether or not a preset second low-frequency transmission condition is satisfied, as illustrated in FIG. 13. The second low-frequency transmission condition is that mod {(tx+T)/(T×120)} is 0.

Here, in a case where the second low-frequency transmission condition is not satisfied, the second core 22 proceeds to S270. On the other hand, in a case where the second low-frequency transmission condition is satisfied, in S260, the second core 22 extracts the vehicle data set as the second low-frequency data in the vehicle data constituting the standardized vehicle data from the standardized vehicle data storage unit 25a, transmits the vehicle data to the management center 3, and proceeds to S270.

When proceeding to S270, the second core 22 determines whether or not a preset third low-frequency transmission condition is satisfied. The third low-frequency transmission condition is that mod {tx/(T×1200)} is 0.

Here, in a case where the third low-frequency transmission condition is not satisfied, the second core 22 proceeds to S290. On the other hand, in a case where the third low-frequency transmission condition is satisfied, in S280, the second core 22 extracts the vehicle data set as the third low-frequency data in the vehicle data constituting the standardized vehicle data from the standardized vehicle data storage unit 25a, transmits the vehicle data to the management center 3, and proceeds to S290.

When the processing proceeds to S290, the second core 22 determines whether or not a preset fourth low-frequency transmission condition is satisfied. The fourth low-frequency transmission condition is that mod {(tx+T)/(T×1200)} is 0.

Here, in a case where the fourth low-frequency transmission condition is not satisfied, the second core 22 proceeds to S310. On the other hand, in a case where the fourth low-frequency transmission condition is satisfied, in S300, the second core 22 extracts the vehicle data set as the fourth low-frequency data in the vehicle data constituting the standardized vehicle data from the standardized vehicle data storage unit 25a, transmits the vehicle data to the management center 3, and proceeds to S310.

When proceeding to S310, the second core 22 determines whether or not a preset event transmission condition is satisfied. The event transmission condition is that mod {tx/(T×172800)} is 0.

Here, in a case where the event transmission condition is not satisfied, the second core 22 proceeds to S330. On the other hand, in a case where the event transmission condition is satisfied, in S320, the second core 22 extracts the vehicle data set as the event data in the vehicle data constituting the standardized vehicle data from the standardized vehicle data storage unit 25a, transmits the vehicle data to the management center 3, and proceeds to S330.

When proceeding to S330, the second core 22 determines whether or not a preset invariant transmission condition is satisfied. The invariant transmission condition is that the current processing in S330 is the first processing in S330 after the microcomputer 11 is activated.

Here, in a case where the invariant transmission condition is not satisfied, the second core 22 ends the data transmission processing. On the other hand, in a case where the invariant transmission condition is satisfied, in S340, the second core 22 extracts the vehicle data set as the invariant data in the vehicle data constituting the standardized vehicle data from the standardized vehicle data storage unit 25a, transmits the vehicle data to the management center 3, and ends the data transmission processing.

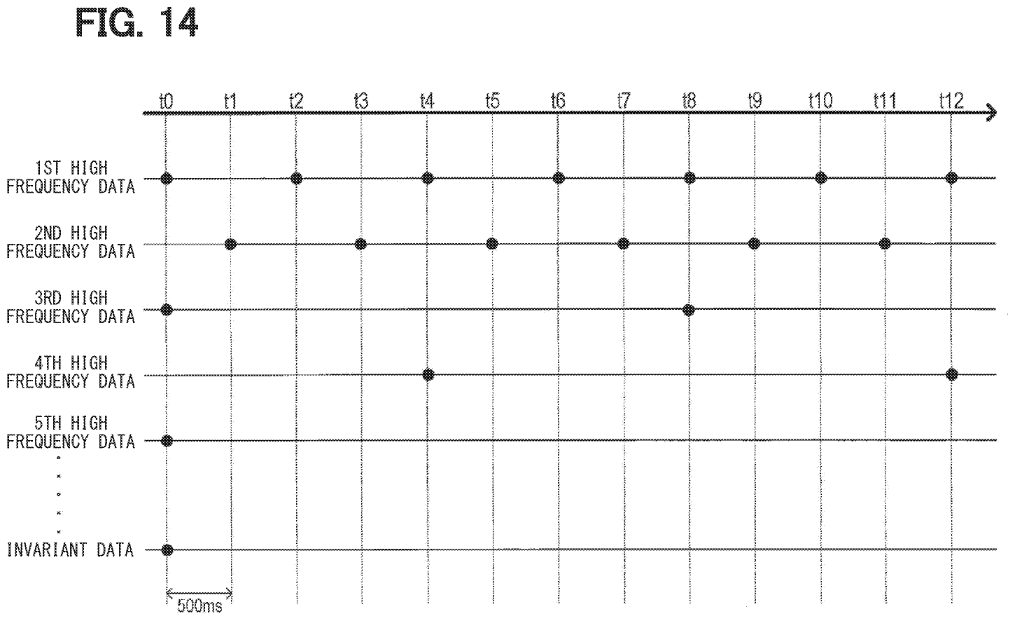

As illustrated in FIG. 14, assuming that a time t0 is the first transmission timing, the first high-frequency data, the third high-frequency data, the fifth high-frequency data, the first low-frequency data, the third low-frequency data, the event data, and the invariant data are transmitted at the time t0.

The first high-frequency data is transmitted every 1,000 ms from the time t0. The second high-frequency data is transmitted at a time t1 when 500 ms has elapsed from the time t0, and is then transmitted every 1,000 ms from the time t1.

The third high-frequency data is transmitted every 4 s from the time t0. The fourth high-frequency data is transmitted at a time t4 when 2 s has elapsed from the time t0, and is then transmitted every 4 s elapses from the time t4.

The fifth high-frequency data is transmitted every 8 s from the time t0. The sixth high-frequency data is transmitted at a time when 4 s has elapsed from the time t0, and is then transmitted every 8 s.

The first low-frequency data is transmitted every minute from the time t0. The second low-frequency data is transmitted at a time when 30 s has elapsed from the time t0, and is then transmitted every minute.

The third low-frequency data is transmitted every ten minutes from the time t0. The fourth low-frequency data is transmitted at a time when five minutes have elapsed from the time t0, and is then transmitted every ten minutes.

The event data is transmitted every 12 hours from the time t0.

The second application 106 of the second unit 102 performs analysis. In a case where the second application 106 is, for example, a driving diagnosis application, the second application 106 detects “sudden steering”, “sudden braking”, and “sudden acceleration”, and outputs analysis results such as “impatient driving” and “slow driving”. In addition, in a case where the second application 106 is, for example, a parking monitoring application, the second application 106 detects “suspicious person detection” and “vehicle intrusion”.

The second application 106 transmits information (hereinafter, analysis information) indicating the detection result or the analysis result to the management center 3. The second application 106 transmits “events” such as “sudden steering” and “suspicious person detection” to the management center 3 at the timing of detection. In addition, the second application 106 transmits “state” such as “impatient driving” to the management center 3 at the timing when “state” is determined, or periodically transmits “state” to the management center 3.

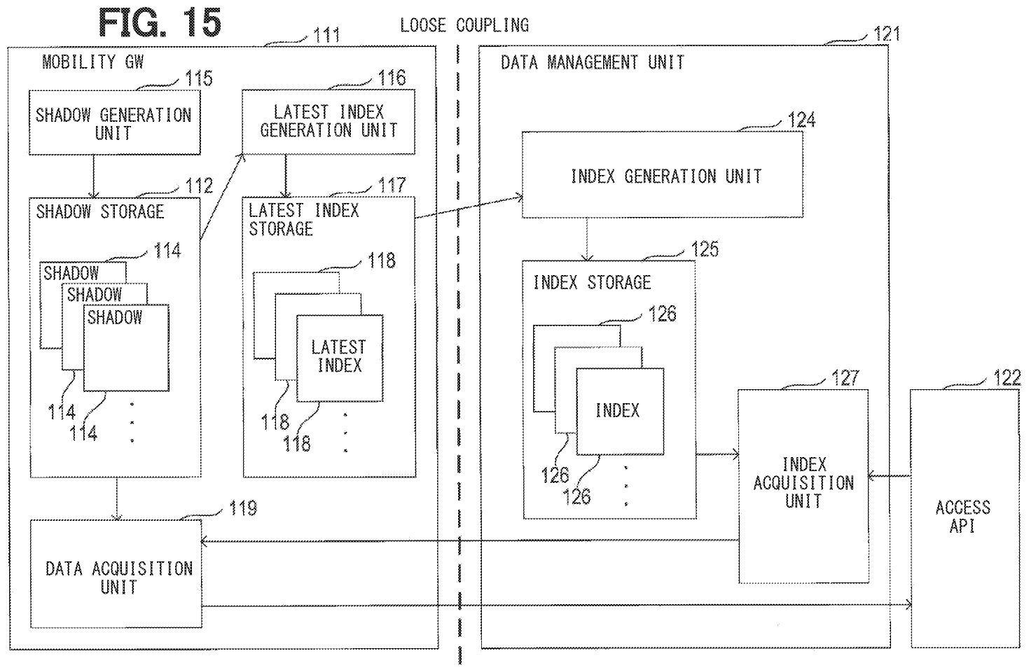

As illustrated in FIG. 15, the mobility GW 111 includes a shadow generation unit 115, a latest index generation unit 116, and a latest index storage unit 117.

Every time vehicle data or analysis information is transmitted from the data collection device 2, the shadow generation unit 115 updates the standardized vehicle data by overwriting the transmitted vehicle data or analysis information over the corresponding area of the structured standardized vehicle data.

Note that in a case where the analysis information related to “state” is not transmitted when the standardized vehicle data is updated, the shadow generation unit 115 copies the previous value to the area corresponding to “state”. In addition, in a case where the analysis information related to “event” is not transmitted when the standardized vehicle data is updated, the shadow generation unit 115 sets “blank (no event)” to the area corresponding to “event”.

The shadow generation unit 115 then generates a new shadow 114 using the updated standardized vehicle data. The shadow generation unit 115 stores the generated shadow 114 in the shadow storage unit 112. As a result, the shadow storage unit 112 stores multiple shadows 114 with different generation times for each vehicle. One shadow 114 is a vehicle data group of a certain vehicle at a predetermined time, and includes a vehicle data group represented by the standardized data structure illustrated in FIG. 10. Although the timing at which the shadow generation unit 115 receives the structured standardized vehicle data via the communication unit 32 varies depending on the vehicle, the new shadow may be generated at the same timing for all the vehicles. The shadow generation unit 115 may generate a new shadow for all the vehicles in a constant cycle. The past shadow 114 is accumulated in the shadow storage unit 112 for each vehicle. The shadows 114 after a certain period may be sequentially deleted.

The shadow generation unit 115 receives the standardized vehicle data formed in the layered structure from the data collection device 2. The shadow generation unit 115 may receive layered structure data of a part of the standardized vehicle data. When generating a new shadow 114 using the updated standardized vehicle data, the shadow generation unit 115 may assign arbitrary information such as a serial number to the shadow and store the information in the shadow storage unit 112.

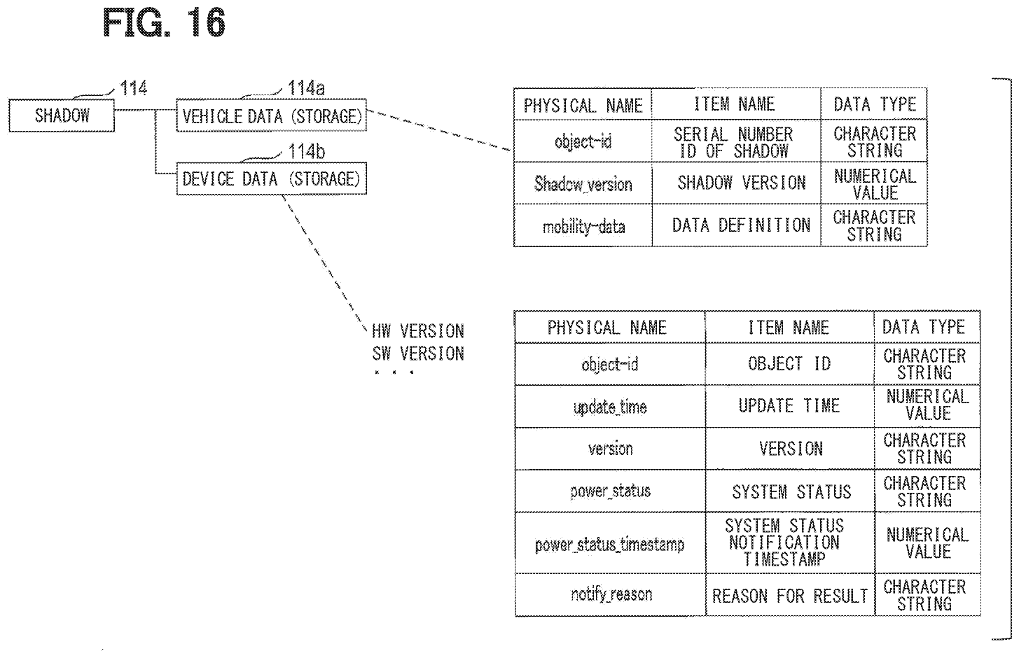

As illustrated in FIG. 16, the shadow 114 includes a vehicle data storage unit 114a and a device data storage unit 114b.

The vehicle data storage unit 114a stores “object-id”, “Shadow_version”, and “mobility-data” as data related to the vehicle on which the data collection device 2 is mounted.

“object-id” is a number for identifying the vehicle. “object-id” is assigned each time a vehicle to be managed is registered in the management center 3.

“Shadow_version” is a numerical value indicating the version of the shadow 114, and a timestamp indicating the time when the shadow is generated is set every time the shadow 114 is generated.

“mobility-data” is the standardized vehicle data described above.

The device data storage unit 114b stores “object-id”, “update_time”, “version”, “power_status”, “power_status_timestamp”, and “notify_reason” as data related to hardware and software installed in the data collection device 2. These pieces of data such as “version” and “power_status” are transmitted from the data collection device 2 separately from the standardized vehicle data when a change occurs.

“object-id” is a character string for identifying the vehicle on which the data collection device 2 is mounted, and functions as a partition key.

“update_time” is a numerical value indicating an update time.

“version” is a character string indicating the version of hardware and software of the data collection device 2.

“power_status” is a character string indicating the system status (ON, OFF, and the like) of the data collection device 2.

“power_status_timestamp” is a numerical value indicating the notification time of the system status.

“notify_reason” is a character string indicating a notification reason.

As described above, the shadow 114 includes information of the data collection device 2 in addition to the vehicle data group. Note that the device data storage unit 114b may store the information of the data collection device 2 in the ROM 42 separately without including the information of the data collection device 2 in the shadow 114. For the information of the data collection device 2, the device data storage unit 114b may store only the latest data in the ROM 42 instead of accumulating the past data for each timestamp.

The latest index generation unit 116 acquires the latest shadow 114 for each vehicle from the shadow storage unit 112, and generates the latest index 118 (also referred to as “first index”) using the acquired shadow 114. The latest index generation unit 116 stores the generated latest index 118 in the latest index storage unit 117. The latest index storage unit 117 stores one latest index 118 for each vehicle. The index is parameter information serving as a key when the shadow 114 is searched in the shadow storage unit 112. The latest index generation unit 116 generates the latest index 118 by using the vehicle data acquired from the data collection device 2 or by generating data by itself.

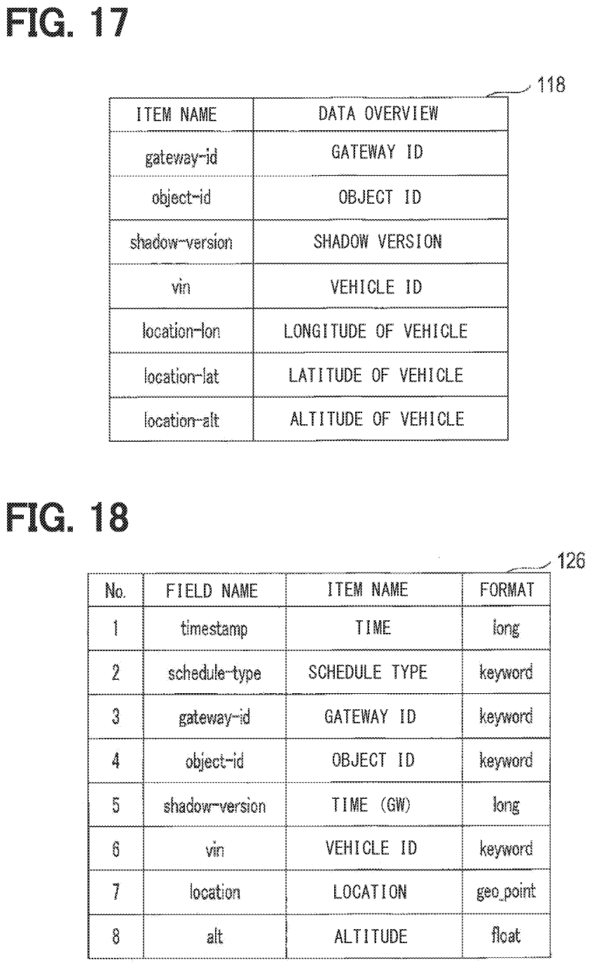

As illustrated in FIG. 17, the latest index 118 stores “gateway-id”, “object-id”, “shadow-version”, “vin”, “location-lon”, “location-lat”, and “location-alt”.

“gateway-id” is information for identifying the mobility GW 111.

“object-id” is information for identifying the vehicle on which the data collection device 2 is mounted.

“shadow-version” corresponds to “Shadow_version” of the shadow 114. That is, “shadow-version” is information for identifying the shadow 114, and the timestamp is set therein.

“vin” is a registration number unique to the vehicle on which the data collection device 2 is mounted.

“location-lon” is information indicating the longitude at which the vehicle having the data collection device 2 mounted thereon is present.

“location-lat” is information indicating the latitude at which the vehicle having the data collection device 2 mounted thereon is present.

“location-alt” is information indicating the altitude at which the vehicle having the data collection device 2 mounted thereon is present.

As illustrated in FIG. 15, the data management unit 121 includes an index generation unit 124 and an index storage unit 125.

The index generation unit 124 periodically acquires the latest index 118 from the latest index storage unit 117, and generates an index 126 (also referred to as “second index”) using the acquired latest index 118. The index generation unit 124 then stores the generated index 126 in the index storage unit 125. As a result, the index storage unit 125 stores multiple indices 126 with different generation times for each vehicle.

As illustrated in FIG. 18, the index 126 stores “timestamp”, “schedule-type”, “gateway-id”, “object-id”, “shadow-version”, “vin”, “location”, and “alt”.

“timestamp” is a timestamp indicating a time in milliseconds.

“schedule-type” indicates whether the scheduler of the data generation source is periodic or an event. In a case where the scheduler is periodic, “schedule-type” is set to “Repeat”, and in a case where the scheduler is an event, “schedule-type” is set to “Event”.

“gateway-id” is information for identifying the mobility GW 111. “object-id” is information for identifying the vehicle on which the data collection device 2 is mounted.

“shadow-version” is a timestamp of the gateway, and is information for identifying the shadow 114. “vin” is a registration number unique to the vehicle on which the data collection device 2 is mounted.

“location” is information indicating the latitude and longitude at which the vehicle on which the data collection device 2 is mounted is present. “alt” is information indicating the altitude at which the vehicle having the data collection device 2 mounted thereon is present.

The latest index generation unit 116 and the latest index storage unit 117 do not need to be provided, and the index generation unit 124 may acquire the shadow 114 stored in the shadow storage unit 112 and generate the index 126. The index generation unit 124 may generate the index 126 by using the latest index 118 acquired from the latest index storage unit 117. This is one of configurations in which the mobility GW 111 and the data management unit 121 are loosely coupled.

In addition, the index generation unit 124 and the index storage unit 125 do not need to be provided. For example, an index acquisition unit 127 requests the data acquisition unit 119 to acquire the designated vehicle data by using “object-id” and the timestamp (“shadow-version”) designated from the access API 122.

As illustrated in FIG. 15, the mobility GW 111 includes a data acquisition unit 119. The data management unit 121 includes the index acquisition unit 127.

The index acquisition unit 127 provides the index 126 capable of specifying the shadow 114 in order to acquire the vehicle data corresponding to the designated parameter from the shadow 114. When receiving a request to instruct acquisition of designated data of the designated vehicle at the designated time from the access API 122, the index acquisition unit 127 acquires the index 126 corresponding to the designated time and the designated vehicle in the received request from the index storage unit 125.

The index acquisition unit 127 determines the shadow 114 specified on the basis of the acquired index 126 as the designated shadow, and transmits a request to instruct acquisition of designated data in the designated shadow to the data acquisition unit 119. Specifically, since the shadow 114 is uniquely determined by “object-id” and “shadow-version”, the index acquisition unit 127 requests the data acquisition unit 119 to acquire the designated data using “object-id” and “shadow-version”.

When receiving the request from the index acquisition unit 127, the data acquisition unit 119 extracts designated data from the designated shadow indicated by the received request, and transmits the extracted designated data to the access API 122. The extracted designated data may be transmitted to the access API 122 via the index acquisition unit 127.

In order to acquire the designated data of the designated vehicle at the designated time, the access API 122 may acquire the corresponding index 126 from the index storage unit 125 via the index acquisition unit 127, and request the data acquisition unit 119 to acquire the designated data using the acquired index 126 (“object-id” and “shadow-version”).

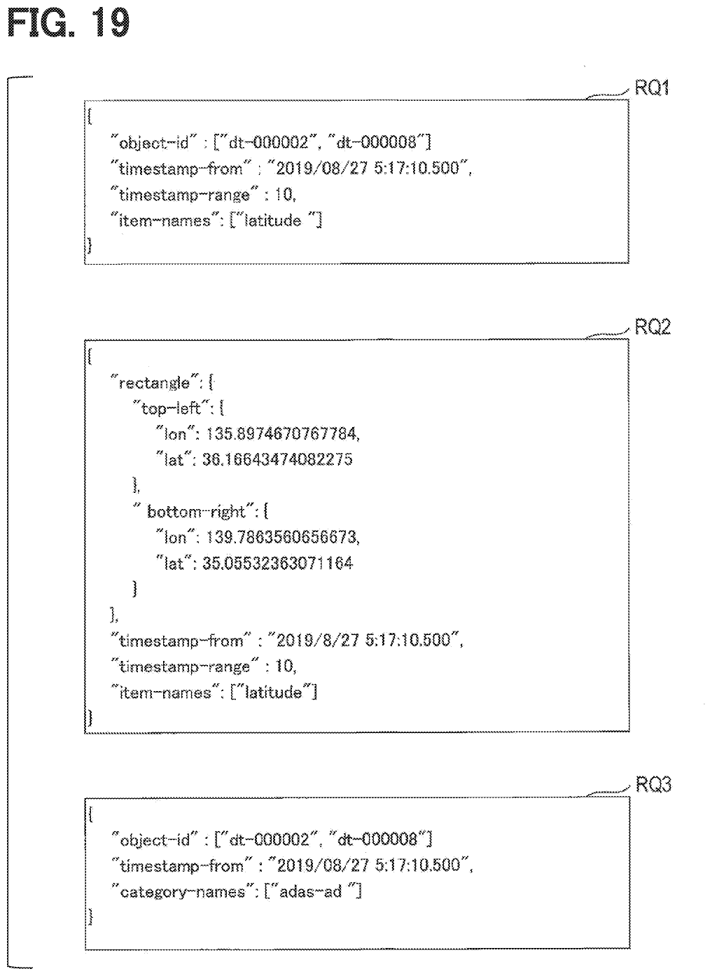

Requests RQ1, RQ2, and RQ3 illustrated in FIG. 19 are specific examples of requests transmitted from the service providing server 4 to the access API 122. In other words, the access API 122 is an API for acquiring vehicle data provided to the service providing server 4.

The request RQ1 is a request to instruct the vehicle whose “object-id” is “dt-000002” and the vehicle whose “object-id” is “dt-000008” to acquire the latitude (that is, data in which “item-names” is “latitude”) for ten seconds from 5:17 10.5, Aug. 27, 2019.

The index acquisition unit 127 acquires “shadow-version” that can specify the shadow 114 corresponding to “object-id” and the time information from the index storage unit 125 via the access API 122 that has received the request RQ1. The index acquisition unit 127 then instructs the data acquisition unit 119 to acquire “latitude” corresponding to “object-id” and “shadow-version”. The data acquisition unit 119 acquires the corresponding vehicle data from the shadow storage unit 112, and the vehicle data is transmitted to the access API 122.

The request RQ2 is a request to instruct acquisition of the latitude of the vehicle present for ten seconds from 5:17 10.5, Aug. 27, 2019 in a rectangular area specified by the upper left point specified by the longitude represented by 135.8974670767784 and the altitude represented by 36.16643474082275 and the lower right point specified by the longitude represented by 139.7863560656673 and the altitude represented by 35.05532363071164.

The index acquisition unit 127 acquires the “object-id” list of vehicles present in the designated area at the designated time from the index storage unit 125 via the access API 122 that has received the request RQ2, and acquires “shadow-version”of the corresponding “object-id” at the designated time. The index acquisition unit 127 then instructs the data acquisition unit 119 to acquire “latitude” corresponding to “object-id” and “shadow-version”. The data acquisition unit 119 acquires the corresponding vehicle data from the shadow storage unit 112, and the vehicle data is transmitted to the access API 122.

The request RQ3 is a request to instruct the vehicle whose “object-id” is “dt-000002” and the vehicle whose “object-id” is “dt-000008” to acquire information of all items in the category “ADAS/AD” at 5:17 10.5, Aug. 27, 2019.

The index acquisition unit 127 acquires “shadow-version” that can specify the shadow 114 corresponding to “object-id” and the time information from the index storage unit 125 via the access API 122 that has received the request RQ3. The index acquisition unit 127 then instructs the data acquisition unit 119 to acquire information of all items in the category “ADAS/AD” corresponding to “object-id” and “shadow-version”. The data acquisition unit 119 acquires the corresponding vehicle data from the shadow storage unit 112, and the vehicle data is transmitted to the access API 122.

In addition, the service providing server 4 can acquire the analysis information by designating the analysis information as designated data of a request transmitted from the service providing server 4 to the access API 122. For example, the index acquisition unit 127 acquires the index 126 corresponding to the designated vehicle and the designated time in the received request from the index storage unit 125. The index acquisition unit 127 determines the shadow 114 specified on the basis of the acquired index 126 as the designated shadow, and transmits a request to instruct acquisition of data of the category “dangerous driving information” in the designated shadow to the data acquisition unit 119. Note that the category “dangerous driving information” includes “sudden steering”, “sudden braking”, and “sudden acceleration” as items. As a result, the service providing server 4 can acquire data including “sudden steering”, “sudden braking”, and “sudden acceleration”.

As indicated by an arrow L1 in FIG. 5, the service providing server 4 accesses the digital twin 123 of the data management unit 121 via the access API 122, thereby specifying the shadow 114 corresponding to the designated vehicle. As indicated by an arrow L2 in FIG. 5, the service providing server 4 transmits a control instruction including the designated shadow and the control content to the vehicle control unit 113 of the mobility GW 111. As a result, the vehicle control unit 113 transmits a control instruction to the data collection device 2 of the vehicle corresponding to the designated shadow. When the control instruction is received by the data collection device 2, control based on the control instruction is executed in the vehicle on which the data collection device 2 is mounted.

The management center 3 with the above configuration includes the vehicle related device 110 and the service related device 120.

The vehicle related device 110 is data-communicably connected to multiple data collection devices 2 individually mounted on multiple vehicles. The service related device 120 can perform data communication with the service providing server 4.

The vehicle related device 110 includes the shadow generation unit 115.

The shadow generation unit 115 repeatedly acquires multiple pieces of vehicle data individually from multiple data collection devices 2, generates, for each vehicle, multiple pieces of vehicle data to which vehicle identification information (in the present embodiment, “object-id”) for identifying the vehicle and timing identification information (in the present embodiment, “Shadow_version”) for identifying the timing at which the vehicle data is acquired are assigned as the shadow 114, and stores the generated data in the shadow storage unit 112 provided in the vehicle related device 110.

The service related device 120 includes the index generation unit 124 and the index acquisition unit 127. The index generation unit 124 generates the index 126 corresponding to each shadow 114 to which the timing identification information is assigned, and stores the index in the index storage unit 125 provided in the service related device 120. The index acquisition unit 127 acquires the index 126 corresponding to the designated parameter from the index storage unit 125.

The vehicle related device 110 further includes the data acquisition unit 119. The data acquisition unit 119 acquires vehicle data from the shadow storage unit 112 using the index 126.

In such a management center 3, the vehicle related device 110 includes the shadow storage unit 112 that stores the shadow 114 including multiple pieces of vehicle data, and the service related device 120 includes the index storage unit 125 that stores the index 126 corresponding to each shadow 114 to which the timing identification information is assigned.

The service related device 120 can specify the shadow 114 by referring to the index 126 (that is, without directly referring to the shadow 114). Since the index 126 is associated with each shadow 114 to which the timing identification information is assigned, it is information that does not depend on the vehicle manufacturer, the vehicle, and the shipping time.

As a result, the management center 3 can cause the service developer to develop the service without considering the difference in the format of the vehicle data, and can achieve both the requirement on the service provider side and the requirement on the vehicle manufacturer side.

In addition, the vehicle related device 110 includes the latest index generation unit 116 that generates the latest index 118 for identifying the latest shadow 114 for each of multiple vehicles and stores the latest index in the latest index storage unit 117 provided in the vehicle related device 110. The index generation unit 124 repeatedly acquires the latest index 118 from the latest index storage unit 117, and generates, as the index 126, the latest index 118 to which time information (in the present embodiment, “timestamp”) for specifying the shadow 114 corresponding to the latest index 118 is assigned.

In addition, the latest index 118 includes vehicle position information (in the present embodiment, “location-lon”, “location-lat”, and “location-alt”) indicating a position where the vehicle is present. The index generation unit 124 then repeatedly acquires the latest index 118 and generates the index 126.

As a result, the management center 3 can search for the index 126 based on the position of the vehicle and acquire the desired index 126.

The index 126 includes specific information (in the present embodiment, “vin”, “location”, and “alt”) for specifying the vehicle necessary for the service providing server 4 to provide a service. As a result, the management center 3 can specify the shadow 114 of the vehicle necessary for providing the service.

The service related device 120 includes the index acquisition unit 127. The index acquisition unit 127 acquires a request to instruct acquisition of designated data of a designated vehicle at a designated time from the service providing server 4, acquires the index 126 corresponding to the designated time and the designated vehicle in the request from the index storage unit 125, and specifies the shadow 114 on the basis of the acquired index 126. The data acquisition unit 119 of the vehicle related device 110 then acquires the designated data included in the shadow 114 specified by the index acquisition unit 127 from the shadow storage unit 112. As a result, the management center 3 can provide the designated data of the designated vehicle at the designated time to the service providing server 4.

The shadow 114 includes information related to a device mounted on the vehicle (in the present embodiment, data stored in the device data storage unit 114b). As a result, the management center 3 can provide information related to the device to the service providing server 4.

The service related device 120 includes the access API 122 for the service providing server 4 to access the service related device 120. As a result, the management center 3 can facilitate access to the management center 3 by the service providing server 4.

The vehicle related device 110 includes the vehicle control unit 113. The vehicle control unit 113 is configured to control a vehicle on which the data collection device 2 is mounted. The vehicle control unit 113 acquires a control instruction to the vehicle from the service providing server 4 without passing the service related device 120. As a result, the management center 3 can omit processing of mediating the control instruction by the service related device 120, and the processing load of the management center 3 can be reduced.

Note that vehicle control unit 113 may acquire the control instruction from the service providing server 4 via the access API 122 of the service related device 120. Providing the access API 122 in the service related device 120 and providing the vehicle control unit 113 in the vehicle related device 110 are also one of the configurations in which the two units are loosely coupled.

In the embodiment described above, the management center 3 corresponds to a center, the data collection device 2 corresponds to an in-vehicle device, the service providing server 4 corresponds to a service providing unit, and the access API 122 corresponds to an application programming interface.

In addition, the data acquisition unit 119 corresponds to a first acquisition unit, and the index acquisition unit 127 corresponds to a second acquisition unit.

Although one embodiment of the present disclosure has been described above, the present disclosure is not limited to the above embodiment, and various modifications can be made.

The control unit 31 and the method thereof described in the present disclosure may be implemented by a dedicated computer provided by configuring a processor and a memory programmed to perform one or multiple functions embodied by a computer program. Alternatively, the control unit 31 and the method thereof described in the present disclosure may be implemented by a dedicated computer provided by configuring a processor with one or more dedicated hardware logic circuits. Alternatively, the control unit 31 and the method thereof described in the present disclosure may be implemented by one or more dedicated computers configured by a combination of a processor and a memory programmed to perform one or multiple functions and a processor configured with one or more hardware logic circuits. The computer program may be stored in a computer-readable non-transition tangible storage medium as an instruction performed by a computer. The method of implementing the functions of the units included in the control unit 31 does not necessarily include software, and all the functions may be implemented using one or multiple pieces of hardware.

Multiple functions of one component in the above embodiment may be implemented by multiple components, or one function of one component may be implemented by multiple components. In addition, multiple functions of multiple components may be implemented by one component, or one function implemented by multiple components may be implemented by one component. A part of the configuration of the embodiment may be omitted. At least a part of the configuration of the embodiment may be added to or replaced with another configuration of the embodiment.

The present disclosure can be implemented in various forms such as a system including the management center 3 as a component, a program for causing a computer to function as the management center 3, a non-transitory tangible storage medium such as a semiconductor memory having the program recorded therein, and a data management method, in addition to the management center 3 described above.

What is claimed is:

1. A center comprising:
a vehicle related device communicably connected with multiple in-vehicle devices individually mounted on multiple vehicles, the vehicle related device performing data communication with the multiple in-vehicle devices; and
a service related device communicably connected with a service providing unit and performing data communication with the service providing unit,
wherein
the vehicle related device includes a shadow generation unit generating, for each of the multiple vehicles, a shadow using multiple pieces of vehicle data repeatedly acquired from the in-vehicle device of corresponding vehicle,
each of the multiple pieces of vehicle data generated as the shadow is assigned with vehicle identification information for identifying the corresponding vehicle and timing identification information for identifying a timing at which each of the multiple pieces of vehicle data is acquired,
the shadow generation unit stores the shadow that includes the multiple pieces of vehicle data in a shadow storage unit provided in the vehicle related device,
the service related device includes:
an index generation unit generating indices corresponding to respective shadows, each of which is assigned with the timing identification information, and stores the generated indices in an index storage unit provided in the service related device; and
an index acquisition unit that acquires, from the index storage unit, one of the indices corresponding to a designated parameter, and
the vehicle related device further includes a data acquisition unit acquiring one of the multiple pieces of vehicle data from the shadow storage unit using the one of the indices, which is acquired corresponding to the designated parameter.

2. The center according to claim 1, wherein
the vehicle related device includes a latest index generation unit that generate latest indices for identifying latest shadows of respective vehicles and store the latest indices in a latest index storage unit provided in the vehicle related device, and
the index generation unit repeatedly acquires the latest indices from the latest index storage unit, and generates, as the indices corresponding to respective shadows, the latest indices, each of which is assigned with time information for specifying the shadow corresponding to the latest index.

3. The center according to claim 2, wherein
each of the latest indices includes vehicle position information indicating a position where the corresponding vehicle is present, and
the index generation unit repeatedly acquires the latest indices for generating the indices corresponding to respective shadows.

4. The center according to claim 1, wherein
each of the indices includes specific information for specifying one of the multiple vehicles, which is necessary for the service providing unit to provide a service.

5. The center according to claim 1, wherein
the index acquisition unit:
acquires, from the service providing unit, a request that instructs acquisition of designated data of a designated vehicle at a designated time;
acquires, from the index storage unit, one of the indices corresponding to the designated time and the designated vehicle in the request; and
specifies one of the shadows based on the acquired index, and
the data acquisition unit of the vehicle related device acquires, from the shadow storage unit, the designated data included in the one of the shadows specified by the index acquisition unit.

6. The center according to claim 1, wherein
each of the shadows includes information related to a device mounted on the corresponding vehicle.

7. The center according to claim 1, wherein
the service related device includes an application programming interface through which the service providing unit accesses the service related device.

8. The center according to claim 1, wherein
the vehicle related device includes a vehicle control unit that controls each of the multiple vehicles on which the multiple in-vehicle device are respectively mounted, and
the vehicle control unit acquires, from the service providing unit, a control instruction to one of the multiple vehicles without going through the service related device.

9. A management method performed by a center, the center including a vehicle related device communicably connected with multiple in-vehicle devices, which are individually mounted on multiple vehicles, for performing data communication and a service related device communicably connected with a service providing unit for performing data communication, the management method comprising:
causing the vehicle related device to repeatedly acquire multiple pieces of vehicle data from each of the multiple in-vehicle devices and generate, for each of the multiple vehicles, a shadow using the acquired multiple pieces of vehicle data, wherein each of the multiple pieces of vehicle data generated as the shadow is assigned with vehicle identification information for identifying the corresponding vehicle and timing identification information for identifying a timing at which each of the multiple pieces of vehicle data is acquired;
causing the vehicle related device to store the multiple pieces of vehicle data in a shadow storage unit provided in the vehicle related device;
causing the service related device to generate indices corresponding to respective shadows, each of which is assigned with the timing identification information, and store the generated indices in an index storage unit provided in the service related device;
causing the service related device to acquire, from the index storage unit, one of the indices corresponding to a designated parameter; and
causing the vehicle related device to acquire one of the multiple pieces of vehicle data from the shadow storage unit using the one of the indices, which is acquired corresponding to the designated parameter.

10. A computer-readable non-transitory storage medium storing a management program for causing a computer included in a center to execute instructions of the management program, the center including a vehicle related device communicably connected with multiple in-vehicle devices, which are individually mounted on multiple vehicles, for performing data communication and a service related device communicably connected with a service providing unit for performing data communication, the instructions comprising:
causing the vehicle related device to repeatedly acquire multiple pieces of vehicle data from each of the multiple in-vehicle devices and generate, for each of the multiple vehicles, a shadow using the acquired multiple pieces of vehicle data, wherein each of the multiple pieces of vehicle data generated as the shadow is assigned with vehicle identification information for identifying the corresponding vehicle and timing identification information for identifying a timing at which each of the multiple pieces of vehicle data is acquired;
causing the vehicle related device to store the multiple pieces of vehicle data in a shadow storage unit provided in the vehicle related device;
causing the service related device to generate indices corresponding to respective shadows, each of which is assigned with the timing identification information, and store the generated indices in an index storage unit provided in the service related device;
causing the service related device to acquire, from the index storage unit, one of the indices corresponding to a designated parameter; and
causing the vehicle related device to acquire one of the multiple pieces of vehicle data from the shadow storage unit using the one of the indices, which is acquired corresponding to the designated parameter.

11. A center comprising:
a vehicle related device communicably connected with multiple in-vehicle devices individually mounted on multiple vehicles, the vehicle related device performing data communication with the multiple in-vehicle devices; and
a service related device communicably connected with a service providing unit and performing data communication with the service providing unit,
wherein
the vehicle related device includes:
a shadow generation unit generating, for each of the multiple vehicles, a shadow using multiple pieces of vehicle data repeatedly acquired from the in-vehicle device of corresponding vehicle, each of the multiple pieces of vehicle data generated as the shadow being assigned with vehicle identification information for identifying the corresponding vehicle and timing identification information for identifying a timing at which each of the multiple pieces of vehicle data is acquired, the shadow generation unit storing the shadow that includes the multiple pieces of vehicle data in a shadow storage unit provided in the vehicle related device;
a first acquisition unit acquiring one of the multiple pieces of vehicle data from the shadow storage unit; and
a vehicle control unit that relays, to one of the multiple vehicles, a request to access the corresponding vehicle, and
the service related device includes:
an access application programming interface that receives a request from the service providing unit; and
a second acquisition unit that requests the vehicle related device to acquire one of the multiple pieces of vehicle data in response to the request received by the access application programming interface.

12. A management method performed by a center, the center including a vehicle related device communicably connected with multiple in-vehicle devices, which are individually mounted on multiple vehicles, for performing data communication and a service related device communicably connected with a service providing unit for performing data communication, the management method comprising:
causing the vehicle related device to repeatedly acquire multiple pieces of vehicle data from each of the multiple in-vehicle devices and generate, for each of the multiple vehicles, a shadow using the acquired multiple pieces of vehicle data, wherein each of the multiple pieces of vehicle data generated as the shadow is assigned with vehicle identification information for identifying the corresponding vehicle and timing identification information for identifying a timing at which each of the multiple pieces of vehicle data is acquired;
causing the vehicle related device to store the multiple pieces of vehicle data in a shadow storage unit provided in the vehicle related device;
causing the vehicle related device to acquire one of the multiple pieces of vehicle data from the shadow storage unit;
causing the vehicle related device to relay, to one of the multiple vehicles, a request to access the corresponding vehicle;
causing the service related device to receive a request from the service providing unit; and
causing the service related device to request the vehicle related device to acquire one of the multiple pieces of vehicle data in response to the request received from the service providing unit.

13. A computer-readable non-transitory storage medium storing a management program for causing a computer included in a center to execute instructions of the management program, the center including a vehicle related device communicably connected with multiple in-vehicle devices, which are individually mounted on multiple vehicles, for performing data communication and a service related device communicably connected with a service providing unit for performing data communication, the instructions comprising:
causing the vehicle related device to repeatedly acquire multiple pieces of vehicle data from each of the multiple in-vehicle devices and generate, for each of the multiple vehicles, a shadow using the acquired multiple pieces of vehicle data, wherein each of the multiple pieces of vehicle data generated as the shadow is assigned with vehicle identification information for identifying the corresponding vehicle and timing identification information for identifying a timing at which each of the multiple pieces of vehicle data is acquired;
causing the vehicle related device to store the multiple pieces of vehicle data in a shadow storage unit provided in the vehicle related device;
causing the vehicle related device to acquire one of the multiple pieces of vehicle data from the shadow storage unit;
causing the vehicle related device to relay, to one of the multiple vehicles, a request to access the corresponding vehicle;
causing the service related device to receive a request from the service providing unit; and
causing the service related device to request the vehicle related device to acquire one of the multiple pieces of vehicle data in response to the request received from the service providing unit.
